(19) United States
(12) Patent Application Publication
(10) Pub. No.: US 2025/0116702 A1
(43) Pub. Date: Apr. 10, 2025

(54) CLOCK SYNCHRONIZATION CIRCUIT

(71) Applicant: Texas Instruments Incorporated, Dallas, TX (US)

(72) Inventors: David P MAGEE, Allen, TX (US); Bassem IBRAHIM, Allen, TX (US); Vishnu RAVINUTHULA, Dallas, TX (US)

(73) Assignee: Texas Instruments Incorporated, Dallas, TX (US)

(21) Appl. No.: 18/588,762

(22) Filed: Feb. 27, 2024

Related U.S. Application Data
(60) Provisional application No. 63/588,012, filed on Oct. 5, 2023.

(51) Int. Cl. G01R 31/317

(52) U.S. Cl. CPC G01R 31/31727; G01R 31/31703; G01R 31/31725

(57) ABSTRACT

A device includes a communication interface, a command processing circuit, a clock synchronization circuit, and a controllable clock source. The command processing circuit has a command input, a reference frequency output, and a reference phase output. The command input is coupled to the communication interface. The clock synchronization circuit has a reference frequency input, a reference phase input, and a frequency control output. The reference frequency output is coupled to the reference frequency input, and the reference phase input coupled to the reference phase output. The clock synchronization circuit includes a frequency synchronization circuit and a phase synchronization circuit. The controllable clock source has a frequency control input and a clock output. The frequency control input is coupled to the frequency control output.

### CROSS-REFERENCE TO RELATED APPLICATIONS

This application claims priority to U.S. Provisional Application No. 63/588,012, filed Oct. 5, 2023, entitled “Clock Synchronization Using Frequency and Phase Correction,” which is hereby incorporated by reference.

### BACKGROUND

Many circuits include an oscillator to provide a clock signal. In a system that include multiple oscillators, the clock signals generated by the oscillators may have mismatches in phase and/or frequency, which can impact the operation of the system.

### SUMMARY

In one example, a device includes a clock source, a counter, a command generation circuit, and a communication interface. The clock source has a clock output. The counter has a counter clock input and a count output. The clock output is coupled to the counter clock input. The command generation circuit has a frequency input, a phase input, and a command output. The frequency input is coupled to the clock output, and the phase input coupled to the count output. The communication interface is coupled to the command output.

In another example, a device includes a communication interface, a command processing circuit, a clock synchronization circuit, and a controllable clock source. The command processing circuit has a command input, a reference frequency output, and a reference phase output. The command input is coupled to the communication interface. The clock synchronization circuit has a reference frequency input, a reference phase input, and a frequency control output. The reference frequency output is coupled to the reference frequency input, and the reference phase input coupled to the reference phase output. The clock synchronization circuit includes a frequency synchronization circuit and a phase synchronization circuit. The controllable clock source has a frequency control input and a clock output. The frequency control input is coupled to the frequency control output.

In another example, an integrated circuit includes a communication interface, a controllable clock source, a counter, a command generation circuit, a command processing circuit, and a clock synchronization circuit. The controllable clock source has a frequency control input and a clock output. The counter has a clock input and a count output. The clock input is coupled to the clock output. The command generation circuit has a frequency input, a phase input, and a command output. The frequency input is coupled to the clock output, the phase input is coupled to the count output, and the command output coupled to the communication interface. The command processing circuit has a command input, a reference phase output, and a reference frequency output. The command input is coupled to the communication interface. The clock synchronization circuit has a reference phase input, a reference frequency input, and a frequency control output. The reference phase input is coupled to the reference phase output. The reference frequency output is coupled to the reference frequency input. The frequency control output is coupled to the frequency control input. The clock synchronization circuit includes a frequency synchronization circuit and a phase synchronization circuit.

In another example, a system includes a device under test (DUT) monitoring device, a first measurement device, and a second measurement device. The DUT monitoring device includes a stimulus generation circuit, an impedance spectroscopy circuit, and a current sense circuit. The stimulus generation circuit has a stimulus output. The impedance spectroscopy circuit has a first spectroscopy input, a second spectroscopy input, and an impedance spectroscopy input. The current sense circuit has a current sense output. The first measurement device includes a synchronization command processing circuit, a clock synchronization circuit, a controllable clock source, a first sampling circuit, and a first processing circuit. The synchronization command processing circuit has a command input. The clock synchronization circuit is coupled to the synchronization command processing circuit. The clock synchronization circuit has a frequency control output. The controllable clock source has a frequency control input and a first clock output. The frequency control input is coupled to the frequency control output. The first sampling circuit has a DUT input, a first sample output, and a first clock input. The first clock input is coupled to the first clock output. The first sampling circuit is configured to receive a voltage measurement signal at the DUT input and provide samples of the voltage measurement signal at the first sample output. The first processing circuit has a first processing input and a first processing output. The first processing input is coupled to the first sample output. The first processing output is coupled to the first spectroscopy input. The first processing circuit is configured to provide first signals representing spectral components of the voltage measurement signal at the first processing output. The second measurement device includes a reference clock source, a counter, a synchronization command generation circuit, a second sampling circuit, and a second processing circuit. The reference clock source has a reference clock output. The counter has a second clock input and a count output. The second clock input is coupled to the reference clock output. The synchronization command generation circuit has a frequency input, a phase input, and a command output. The frequency input is coupled to the reference clock output, the phase input is coupled to the count output, and the command output is coupled to the command input. The second sampling circuit has a current sense input, a second sample output, and a third clock input. The third clock input is coupled to the reference clock output, and the current sense input is coupled to the current sense output. The second sampling circuit is configured to receive a current measurement signal at the current sense input and provide samples of the current measurement signal at the second sample output. The second processing circuit has a second processing input and a second processing output. The second processing input is coupled to the second sample output, and the second processing output is coupled to the second spectroscopy input. The second processing circuit is configured to provide second signals representing spectral components of the current measurement signal at the second processing output.

In another example, a method includes generating, by a first device, a reference clock signal, and providing, by the first device, a reference count value based on counting cycles of the reference clock signal. The method also includes providing, by the first device, a divided clock signal based on dividing the reference clock signal, providing, by the first device, a first command including the divided clock signal, and providing, by the first device, a second command including the reference count value. The method further includes receiving, by a second device, the first command and the second command, and generating, by the second device, a target clock signal. The method yet further includes determining, by the second device, a target count value based on the target clock signal, and adjusting, by the second device, a frequency and a phase of the target clock signal based on the divided clock signal and a difference between the reference count value and the target count value.

### BRIEF DESCRIPTION OF THE DRAWINGS

FIG. 1 is a block diagram of an example system for monitoring a state of a device under test (DUT).

FIGS. 2 and 3 are block diagrams of systems including devices coupled to one another for command communication.

FIG. 4 is a timing diagram showing example timing of reference and target clocks in a system.

FIG. 5 is a block diagram of an example system that provides clock synchronization via command transmission.

FIG. 6 is a block diagram of example circuitry of a target device for providing clock synchronization based on commands received from a reference device.

FIG. 7 is a block diagram of an example integrated circuit that includes battery monitoring circuitry and circuitry for clock synchronization via a communication interface.

FIG. 8 is a flow diagram of an example method of clock synchronization via a communication interface.

FIG. 9 is a flow diagram of an example method of generating synchronization commands in a reference device.

FIG. 10 is a flow diagram of an example method of phase synchronization in a target device.

FIG. 11 is a timing diagram showing frequency and phase synchronization communication between reference and target devices.

FIGS. 12A, 12B, and 12C are diagrams of frequency and phase synchronization commands suitable for use in the system of FIG. 5.

FIG. 13 is a graph of example synchronization timing error with and without randomization of frequency synchronization commands.

FIG. 14 is a graph of example synchronization timing error with and without phase synchronization commands.

FIG. 15 is a flow diagram of an example method of clock synchronization using frequency and phase synchronization.

### DETAILED DESCRIPTION

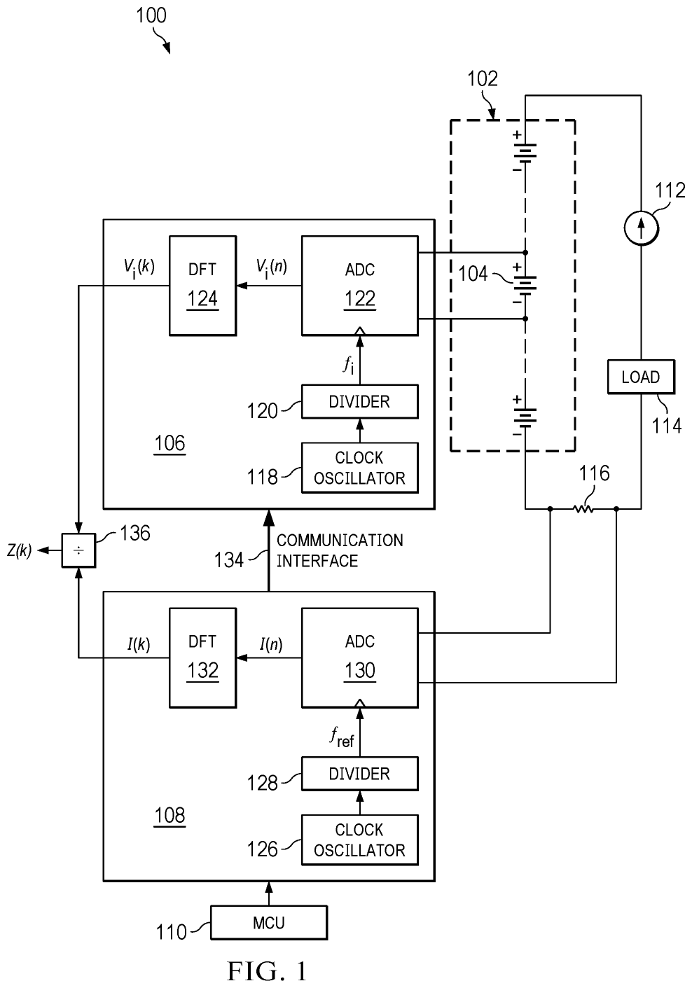

FIG. 1 is a block diagram of an example system 100 for monitoring a state of a DUT. The DUT may be a target device that is analyzed in the frequency domain using a spectroscopy method, such as impedance spectroscopy. Examples of the DUT can include a charge storage device (e.g., a battery, a capacitor, a super capacitor, etc.), a motor, a sensor, etc. In the example shown in FIG. 1, the system 100 includes a battery pack 102 as the DUT. The battery pack 102 contains multiple batteries, such as the battery 104, connected in series. The battery pack 102 may power a vehicle (e.g., an electric or hybrid vehicle), a power tool, or other battery powered device. In other examples, the system 100 may include other types of DUTs.

In addition to the battery pack 102, the system 100 also includes a voltage measurement circuit 106, a current measurement circuit 108, a controller 110, an excitation current source 112, a load 114, and a sense resistor 116. The excitation current source 112, the load 114, and the sense resistor 116 are coupled in series between a positive terminal of the battery pack 102 and a negative terminal of the battery pack 102. The excitation current source 112 generates an excitation current for measuring the impedance of the battery 104. The current measurement circuit 108 and/or the voltage measurement circuit 106 are coupled to the controller 110 (e.g., via a serial communication bus). The controller 110 provides control information to, and retrieves status information from, the voltage measurement circuit 106 and the current measurement circuit 108. The voltage measurement circuit 106 can also be coupled to the current measurement circuit 108 via a data interface 134. The data interface 134 may be a serial bus that provides for exchange of information between the current measurement circuit 108 and the voltage measurement circuit 106.

The voltage measurement circuit 106 includes a clock oscillator 118, a frequency divider 120, an analog-to-digital converter (ADC) 122, and a discrete frequency transform (DFT) circuit 124. The clock oscillator 118 generates a clock signal that is divided by the frequency divider 120 to produce a conversion clock that sets the timing of acquisition by the ADC 122. The ADC 122 samples the voltage of the battery 104 while the excitation current source 112 is generating the excitation current. The ADC 122 provides voltage measurement values representing the voltage samples to the DFT circuit 124, and the DFT circuit 124 transforms the voltage measurement values to the frequency domain, represented by Vᵢ(k) in FIG. 1.

The current measurement circuit 108 includes a clock oscillator 126, a frequency divider 128, an analog-to-digital converter (ADC) 130, and a discrete frequency transform (DFT) circuit 132. The clock oscillator 126 generates a clock signal that is divided by the frequency divider 128 to produce a conversion clock that sets the timing of acquisition by the ADC 130. The ADC 130 samples the voltage across the sense resistor 116, which represents the current flowing through the sense resistor 116 and the battery pack 102, while the excitation current source 112 is generating the excitation current. The ADC 130 provides measurement values representing the current samples to the DFT circuit 132, and the DFT circuit 132 transforms the current measurement values to the frequency domain, represented by I(k) in FIG. 1.

The voltage measurement circuit 106 provides the voltage measurement values, and the current measurement circuit 108 provides the current measurement values, to an impedance computation circuit 136. The impedance computation circuit 136 may divide the voltage measurement values by the current measurement values at selected frequencies to provide an impedance spectroscopy analysis of the battery 104 at the selected frequencies. Information related to the state of the battery 104 can be determined based on the impedance spectroscopy analysis of the battery 104. For example, the internal temperature of the battery 104 may be determined based on the measured impedance spectroscopy analysis of the battery 104.

The accuracy of the impedance measurements provided by the system 100 is affected by the timing of the voltage and current sampling performed by the voltage measurement circuit 106 and the current measurement circuit 108. Differences in the sampling time of the voltage by the voltage measurement circuit 106 relative to the sampling time of the current by the current measurement circuit 108 can introduce misalignment in the sampling times of the voltage (by the voltage measurement circuit 106) and of the current (by the current measurement circuit 108). The misalignment can lead to non-correspondence between the voltage and current samples, which can reduce the accuracy of the impedance values, and reduce the accuracy of battery state information derived from the impedance values. The sampling by the voltage measurement circuit 106 and the current measurement circuit 108 may be synchronized for precise post-processing of data and for generating time aligned control commands. However, synchronization may be challenging, because the voltage measurement circuit 106 and current measurement circuit 108 have different clocks to determine the timing of local data measurements, where the clocks are based on the clock oscillator 118 and the clock oscillator 126. The frequencies of the clock oscillator 118 and clock oscillator 126 vary independently, with temperature and other factors. Calibration of the clock oscillator 118 and clock oscillator 126 may be insufficient to ensure the same clock source frequency during device operation due to temperature variations between devices and with time. Accordingly, the voltage measurement circuit 106 and the current measurement circuit 108 may not be properly synchronized, or may operate asynchronously with different clock frequencies, which may result in time misalignment between measurements that may introduce error in the impedance measurements.

In the system 100, the clock oscillator 118 and the clock oscillator 126, and the sampling of voltage and current by the voltage measurement circuit 106 and the current measurement circuit 108, can be synchronized to improve the accuracy of the impedance values. In the system 100, the clock oscillator 118 of the voltage measurement circuit 106 can be synchronized to the clock oscillator 126 of the current measurement circuit 108 by transferring synchronization information via the data interface 134. The synchronization information can include frequency information and phase information provided by the current measurement circuit 108, and transferred to the voltage measurement circuit 106 via the data interface 134. The voltage measurement circuit 106 can apply the frequency and phase information to adjust the frequency and the phase of the clock signal generated by the clock oscillator 118 to match the frequency and phase of the clock signal generated by the clock oscillator 126 within an acceptable timing error (e.g. less than 3 micro-seconds), and synchronize sampling by the ADC 122 with sampling by the ADC 130.

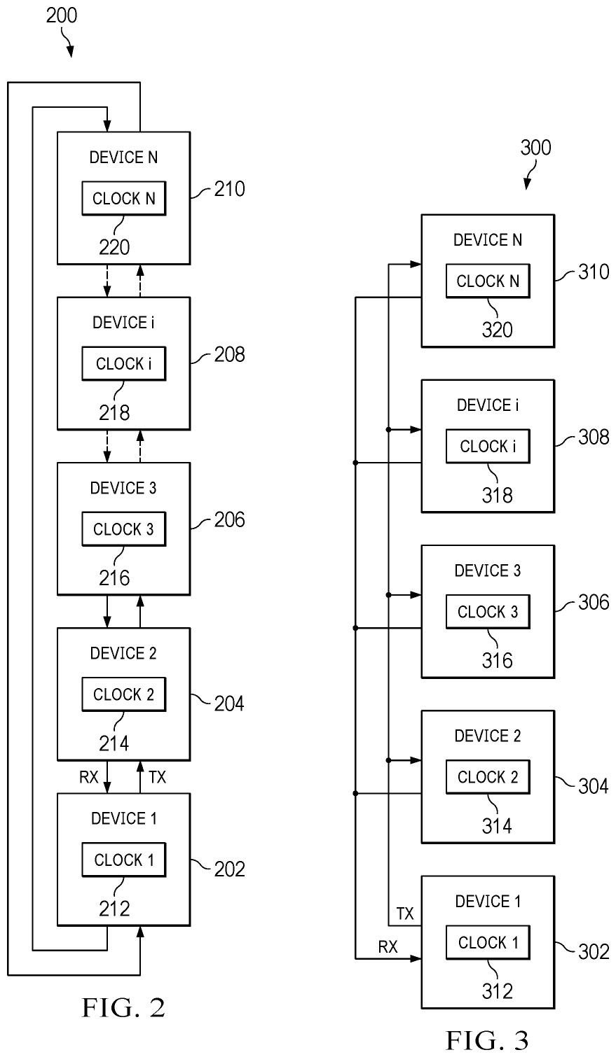

In examples of the system 100, the devices used to sample voltage and current can be connected in multiple topologies such as ring and bus topologies. FIG. 2 shows a system 200, including devices 202, 204, 206, 208, and 210 connected in a ring topology. In the ring topology of the system 200, commands are transferred serially from one device to another passing through intermediate devices. FIG. 3 shows a system 300, including devices 302, 304, 306, 308, and 310 connected in a bus topology. In the bus topology of the system 300, commands can be transferred from one reference device to all target devices in parallel. Examples of the system 100 may be implemented using bus or ring topologies.

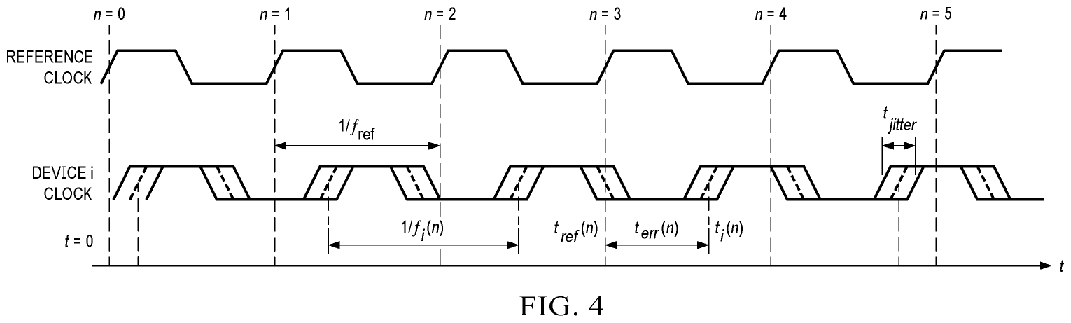

FIG. 4 is a timing diagram showing example timing of reference and target clocks in the system 100. In FIG. 4, the reference clock is labeled Ref. Clock, and the target clock is labeled Device i Clock. The clock oscillator 126 provides the reference clock and the clock oscillator 118 provides the target clock. Considering frequency f_{ref} of the reference clock and frequency fᵢ(n) of the i^{th} target device (e.g., the voltage measurement circuit 106) at time sample n, the rising transition of each clock is defined as t_{ref}(n) and tᵢ(n) as shown in FIG. 4. The target device clock frequency includes cycle to cycle variation in frequency based on temperature variation and includes the effect of clock jitter tⱼᵢₜₜₑᵣ. The time error between clocks is defined as:

$${t}_{err \_ i} ( n ) = {t}_{ref} ( n ) - {t}_{i} ( n ) \qquad ( 1 )$$

In the system 100, the clock oscillator 118 and the clock oscillator 126 are synchronized to minimize the sum of squared time error for the i^{th} target device during a measurement duration that is defined as Σₙ₌₁^{N}t_{err_i}(n)², where N is the number of clock cycles of the measurement duration.

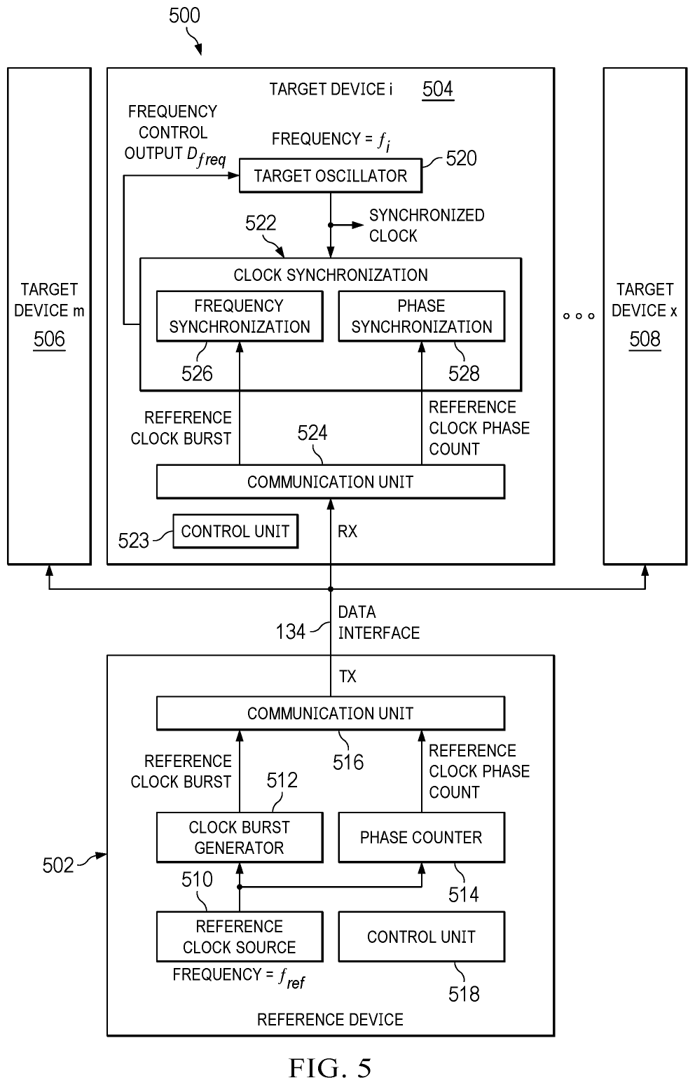

FIG. 5 is a block diagram of an example system 500 that provides clock synchronization via command transmission. The system 500 is an example of the system 100. The system 500 includes a reference device 502, and target devices 504, 506, and 508 coupled to the reference device 502 via a communication interface. Examples of the system 500 may include any number of target devices coupled to the reference device 502. The target device 506 and the target device 508 may include circuitry similar to that described with reference to the target device 504. Synchronization operations described with respect to the target device 504 are also applicable to the target device 506 and the target device 508.

The reference device 502 provides frequency and phase information to the target device 504 to synchronize the clock generated by the target device 504 to the clock generated by the reference device 502 by, for example, reducing the phase and/or frequency mismatches between the clocks. The reference device 502 includes a reference clock source 510, a clock burst generator 512, a phase counter 514, a communication unit 516, and a control unit 518. The reference clock source 510 generates a reference clock for timing operations of the reference device 502. An output of the reference clock source 510 (at which the reference clock is provided) is coupled to an input of the clock burst generator 512, and an input of the phase counter 514. Each reference device 502 can include an application specific integrated circuit (ASIC), or a programmable logic circuit, a programmable controller, etc., configured (e.g., by instructions) to control the operations of various components of the device. For example, control unit 518 of reference device 502 can be a programmable controller.

The clock burst generator 512 generates a burst of cycles of the reference clock, or a divided version of the reference clock, for use in synchronizing the target device 504. For example, the clock burst generator 512 may include a divider circuit that divides the reference clock by an integer value to produce a lower frequency reference clock burst that is provided to the communication unit 516. An output of the clock burst generator 512 (at which the reference clock burst is provided) is coupled to an input of the communication unit 516.

The phase counter 514 counts cycles of the reference clock within a selected phase determination time interval. An output of the phase counter 514 is coupled to an input of the communication unit 516. The phase counter 514 provides the count of reference clock cycles at the output as a reference clock phase count.

The communication unit 516 receives the reference clock burst from the clock burst generator 512 and the reference clock phase count from the phase counter 514. The communication unit 516 includes a command generation circuit that generates synchronization commands based on the reference clock burst and the reference clock phase count. The communication unit 516 can periodically transmit the synchronization commands including the reference clock burst and/or the reference clock phase count to the target device 504 to adjust the frequency and phase of the target clock generated by the target device 504. For example, the communication unit 516 may broadcast a first command including the reference clock burst to the target devices 504, 506, and 508, and broadcast a second command including the reference clock phase count to the target devices 504, 506, and 508. In some examples, the communication unit 516 may transmit a command including the reference clock burst and the reference clock phase count to the target device 504. The control unit 518 is coupled to the clock burst generator 512, the phase counter 514, and the communication unit 516 to control generation of the reference clock burst, the reference clock phase count, and the synchronization commands.

The target device 504 receives synchronization commands transmitted by the reference device 502, and applies the reference clock burst and the reference clock phase count to synchronize a target clock generated by the target device 504 to the reference clock generated by the reference device 502. The target device 504 includes a control unit 523, a communication unit 524, a clock synchronization circuit 522, and a target oscillator 520. An input of the communication unit 524 is coupled to an output of the communication unit 516 via the data interface 134, and an output of the communication unit 524 is coupled to the clock synchronization circuit 522. The communication unit 524 receives the synchronization commands transmitted by the reference device 502. The communication unit 524 includes a command processing circuit that extracts the reference clock burst and the reference clock count from the synchronization commands, and provides the reference clock burst and the reference clock phase count to the clock synchronization circuit 522. Each target device, including target device 504, can include an application specific integrated circuit (ASIC), or a programmable logic circuit, a programmable controller, etc., configured (e.g., by instructions) to control the operations of various components of the device. For example, control unit 523 can be a programmable controller.

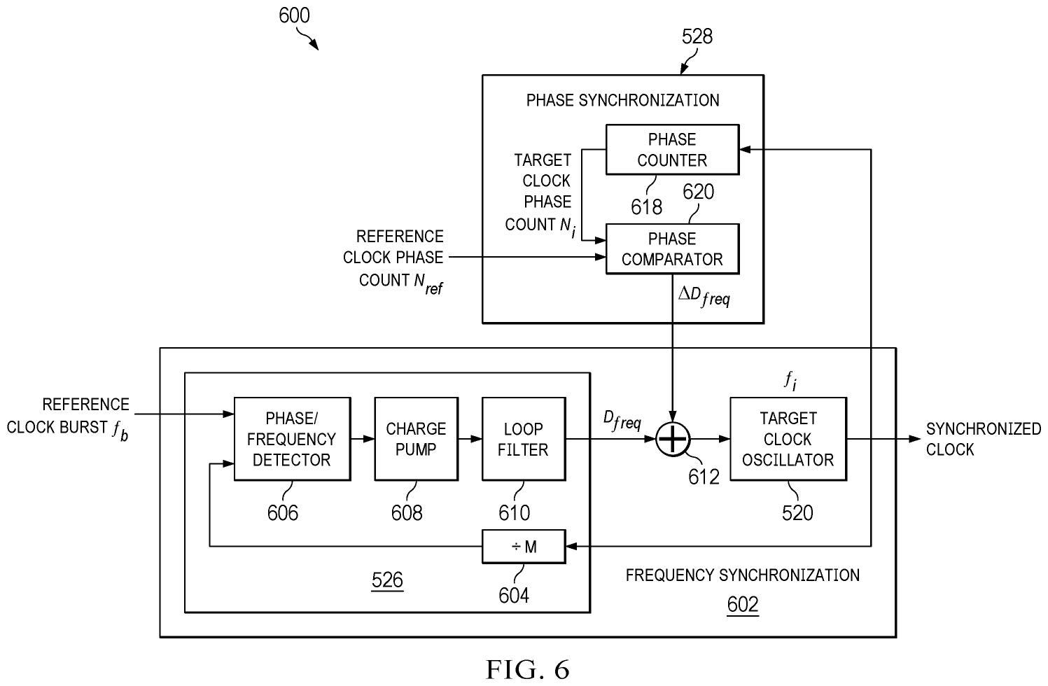

The clock synchronization circuit 522 includes a frequency synchronization circuit 526 and a phase synchronization circuit 528. An output of the clock synchronization circuit 522 is coupled to an input of the target oscillator 520, and an input of the clock synchronization circuit 522 is coupled to an output of the target oscillator 520. The clock synchronization circuit 522 controls the frequency and phase of the target clock generated by the target oscillator 520 (shown in FIG. 5 as “synchronized clock”). The frequency synchronization circuit 526 provides a frequency control signal to the target oscillator 520 to adjust the frequency of the target clock based on a comparison of the frequency of the target clock to the frequency of the reference clock burst. The phase synchronization circuit 528 provides a phase control signal (labelled ΔD_{freq} in FIG. 6) to the target oscillator 520 to adjust the phase of the target clock based on a comparison of the reference clock phase count to a target clock phase count. The target clock phase count is a count of target clock cycles in the phase determination time interval. The clock synchronization circuit 522 may provide the frequency control signal and the phase control signal sequentially or concurrently. In some examples, various functions of phase synchronization circuit 528 can be implemented using a programmable controller, a programmable logic circuit, an ASIC, etc. For example, phase counter 618 and phase comparator 620 can be circuits or implemented by a programmable controller executing software instructions.

In some examples, reference device 502 can be part of or include a measurement device (e.g., voltage measurement circuit 106, current measurement circuit 108, etc.), and target devices 506/508 can be part of or include another measurement device (e.g., voltage measurement circuit 106, current measurement circuit 108, etc.), the clock synchronization operations can be performed to reduce sampling time/frequency mismatches between voltage and current. In some examples, reference device 502/target devices 506/508 do not have sampling circuits (e.g., ADC 122/130). For example, reference device 502/target devices 506/508 can be part of controller 110 of FIG. 1. The clock synchronization operations can be performed to reduce time/frequency mismatches among, for example, the excitation current provided by excitation current source 112 and the sampling of the current and the voltage of battery 104 in response to the excitation current.

FIG. 6 is a block diagram of example circuitry 600 of the target device 504 for providing target clock synchronization based on commands received from the reference device 502. The circuitry 600 includes the phase synchronization circuit 528 and a phase-locked loop circuit 602. The phase-locked loop circuit 602 includes the target oscillator 520 and the frequency synchronization circuit 526. The frequency synchronization circuit 526 includes a frequency divider 604, a phase detector 606, a charge pump 608, and a loop filter 610. The frequency divider 604 has an input coupled to the output of the target oscillator 520. The frequency divider 604 divides the target clock generated by the target oscillator 520 by a divisor to produce a divided target clock for comparison to the reference clock burst. An output of the frequency divider 604 is coupled to a first detector input of the phase detector 606. A second detector input of the phase detector 606 is coupled to the communication unit 524 for receipt of the reference clock burst transmitted by the reference device 502.

The phase detector 606 compares the reference clock burst to the divided target clock, and provides an error signal representing the difference in frequency of the divided target clock and the reference clock burst. The phase detector 606 produces the error signal periodically, e.g., when a command including the reference clock burst is received. The charge pump 608 has an input coupled to the detector output of the phase detector 606. The phase detector 606 can sink or source current based on the error signal received from the phase detector 606. The loop filter 610 averages the error signal (as represented by the charge pump output signal) to control the frequency of the target oscillator 520. An output signal of the frequency synchronization circuit 526 is provided by the loop filter 610 to a first input of a summing circuit 612. A second input of the summing circuit 612 is coupled to the phase synchronization circuit 528. An output of the summing circuit 612 is coupled to an input of the target oscillator 520 to control the frequency and phase of the target clock.

The phase synchronization circuit 528 includes a phase counter 618 and a phase comparator 620. The phase counter 618 has an input coupled to the output of the target oscillator 520. The phase counter 618 counts cycles of the target clock in the phase determination time interval to produce a target clock phase count. An output of the phase counter 618 is coupled to a first input of the phase comparator 620. A second input of the phase comparator 620 is coupled to the communication unit 524 for receipt of the reference clock phase count transmitted by the reference device 502. The phase comparator 620 compares the target clock phase count and the reference clock phase count, and generates a difference signal that is representative of the difference between the target clock phase count and the reference clock phase count. A comparator output of the phase comparator 620 is coupled to the second input of the summing circuit 612 to adjust the phase of the target clock.

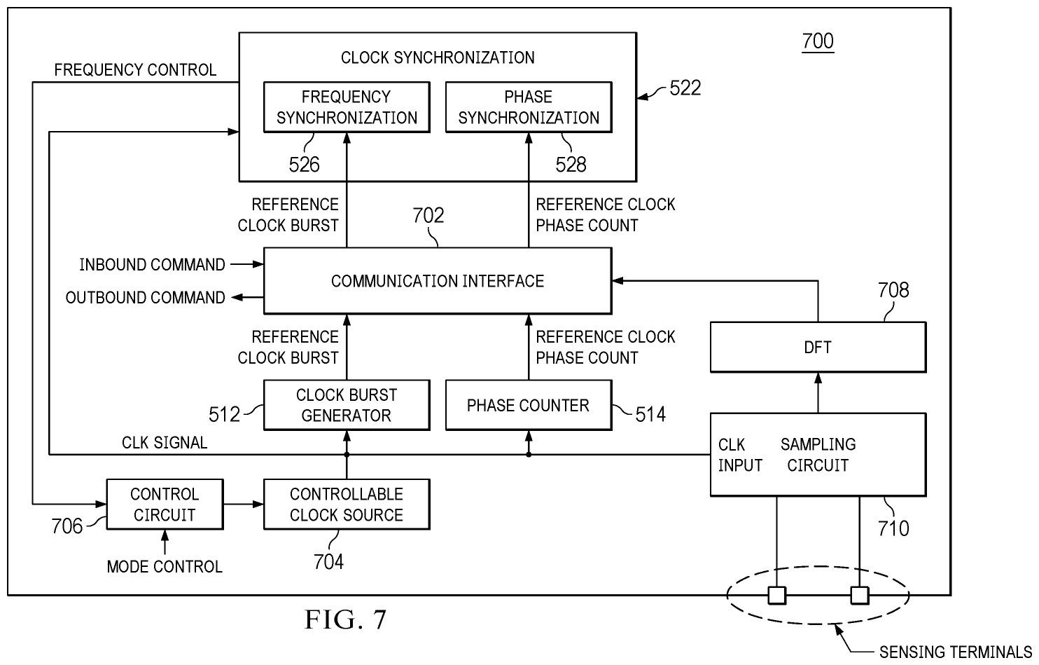

FIG. 7 is a block diagram of an example integrated circuit 700 that includes battery monitoring circuitry and circuitry for clock synchronization. The integrated circuit 700 is configurable to operate as a reference device that transmits clock synchronization commands, or as a target device that receives clock synchronization commands and synchronizes a target clock to a reference clock based on the received synchronization commands. The integrated circuit 700 includes the clock burst generator 512, the phase counter 514, the clock synchronization circuit 522, a communication interface 702, a controllable clock source 704, a mode control circuit 706, a DFT circuit 708, and a sampling circuit 710.

The sampling circuit 710 can include an ADC (such as the ADC 122 or 130 shown in FIG. 1) for digitizing a voltage or current measurement. A sampling clock input of the sampling circuit 710 is coupled to a clock output of the controllable clock source 704. Sensing terminals of the sampling circuit 710 can be coupled to the battery 104 to sense a voltage signal, or the sense resistor 116 to sense a current signal, as shown in FIG. 1.

The DFT circuit 708 is a signal processing circuit and can be an example of the DFT circuit 124 or the DFT circuit 132 shown in FIG. 1. An input of the DFT circuit 708 is coupled to an output of the sampling circuit 710. The DFT circuit 708 transforms time-domain digital measurement values received from the sampling circuit 710 to frequency domain measurement values. An output of the DFT circuit 708 is coupled to the communication interface 702 for communication of the frequency domain measurement values to an external circuit that can compute impedance based on the frequency domain measurement values. In some examples, DFT circuit 708 can be a digital signal processor (DSP). In some examples, DFT circuit 708 can be part of an ASIC, a programmable logic circuit, etc., configured to perform the transform operations. The communication interface 702 can operate as the communication unit 516 or the communication unit 524 shown in FIG. 5. If the integrated circuit 700 is configured to operate as a reference device, then the communication interface 702 operates as the communication unit 516. If the integrated circuit 700 is configured to operate as a target device, then the communication interface 702 operates as the communication unit 524.

The controllable clock source 704 can operate as the reference clock source 510 or the target oscillator 520 shown in FIG. 5. If the integrated circuit 700 is configured as a reference device, then the controllable clock source 704 operates as the reference clock source 510. If the integrated circuit 700 is configured as a target device, then the controllable clock source 704 operates as the target oscillator 520.

The mode control circuit 706 provides frequency/phase control signals to the controllable clock source 704 if the integrated circuit 700 is operating as a target device. The mode control circuit 706 has a mode control input for receipt of a mode control signal that specifies whether the integrated circuit 700 is operating as reference device or a target device. For example, a first state of the mode control signal may specify that the integrated circuit 700 is to operate as a reference device, and a second state of the mode control signal may specify that the integrated circuit 700 is to operate as a target device. The mode control signal may be provided from a control register (not shown) of the integrated circuit 700. The mode control circuit 706 has a frequency control input coupled to an output of the clock synchronization circuit 522, and an output coupled to an input of the controllable clock source 704. The mode control circuit 706 can also control the operations of various components of integrated circuit 700 such as the clock burst generator 512, the phase counter 514, the clock synchronization circuit 522, the communication interface 702, the DFT circuit 708, and the sampling circuit 710. In some examples, mode control circuit 706 can be a programmable controller.

If the integrated circuit 700 is operating as a reference device, the mode control circuit 706 can provide a steady state signal to the controllable clock source 704. If the integrated circuit 700 is operating as a reference device, the mode control circuit 706 can also cause the communication interface 702 to operate as the communication unit 516, and can control the clock burst generator 512 and phase counter 514 to initiate generation of the reference clock burst and the reference clock phase count. If the integrated circuit 700 is operating as a target device, the mode control circuit 706 can cause the communication interface 702 to operate as the communication unit 524, and enable operation of the clock synchronization circuit 522.

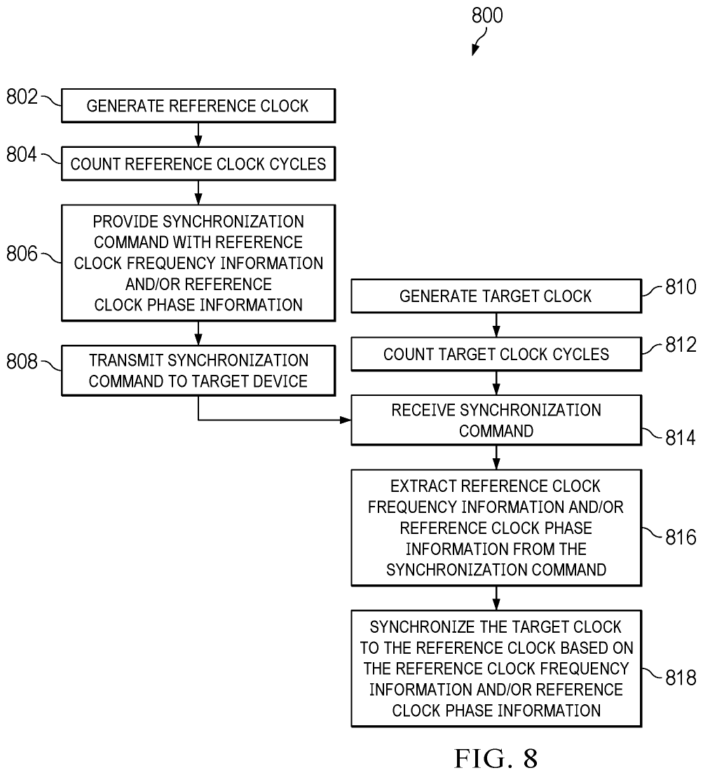

FIG. 8 is a flow diagram of an example method 800 of clock synchronization via a communication interface. Though depicted sequentially as a matter of convenience, at least some of the actions shown can be performed in a different order and/or performed in parallel. Additionally, some implementations may perform only some of the actions shown. Operations of the method 800 may be performed by an implementation of the system 500. For example, the operations of blocks 802 through 808 can be performed by the reference device 502, and operations of blocks 810 through 818 can be performed by the target device 504.

In block 802, the reference clock source 510 generates a reference clock. In block 810, the target oscillator 520 generates a target clock.

In block 804, the phase counter 514 counts cycles of the reference clock in a phase determination time interval. In block 812, a phase counter of the phase synchronization circuit 528 counts cycles of the target clock in the phase determination time interval.

In block 806, the reference device 502 (e.g., a command generation circuit of the reference device 502) generates a synchronization command that includes reference clock frequency information and/or reference clock phase information. For example, the reference device 502 can generate a reference clock burst that includes reference clock frequency information and generate a command that includes the reference clock burst. The reference device 502 can also generate a command that includes the count of cycles of the reference clock during the phase determination time interval (reference clock phase count), where the count of cycles is the reference clock phase information.

In block 808, the reference device 502 transmits the synchronization command to the target device.

In block 814, the target device 504 receives the synchronization command transmitted by the reference device 502.

In block 816, the target device 504 (e.g., a command processing circuit of the target device 504), extracts the reference clock frequency information and/or the reference clock phase information from the synchronization command. For example, the target device 504 can identify the synchronization command as including a reference clock burst, and provide the reference clock burst to the frequency synchronization circuit 526. Similarly, the target device 504 can identify the synchronization command as including the reference clock phase count, and provide the reference clock phase count to the phase synchronization circuit 528.

In block 818, the target device 504 synchronizes the target clock to the reference clock based on the reference clock frequency information and/or the reference clock phase information provided by the reference device 502.

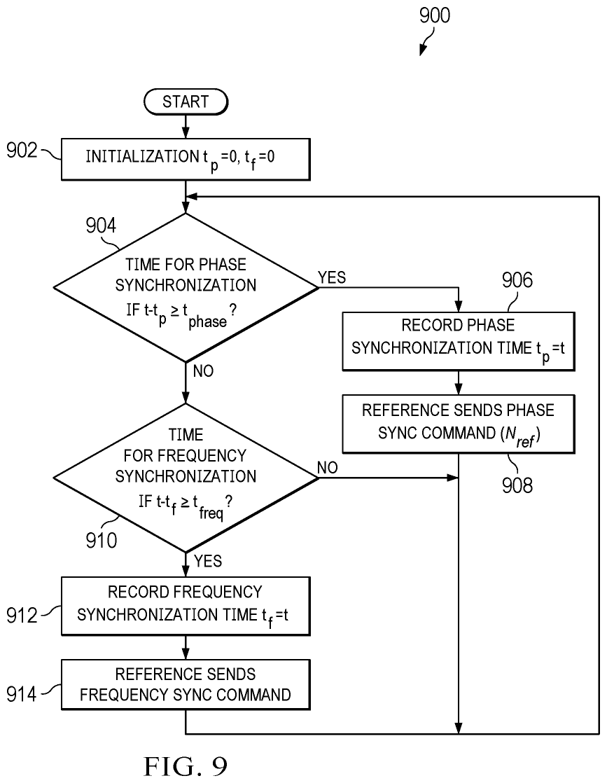

FIG. 9 is a flow diagram of an example method 900 of generating synchronization commands in the reference device 502. Though depicted sequentially as a matter of convenience, at least some of the actions shown can be performed in a different order and/or performed in parallel. Additionally, some implementations may perform only some of the actions shown.

In block 902, the reference device 502 (e.g., the control unit 518 of the reference device 502) initializes frequency and phase synchronization time values.

In block 904, the reference device 502 (e.g., the control unit 518) determines whether it is currently time to provide phase synchronization to the target device 504. The determination is based on whether a phase synchronization time interval tₚₕₐₛₑ has elapsed from the last phase synchronization time tₚ. If the difference between current time (t) and the last phase synchronization tₚ is less than tₚₕₐₛₑ, the control unit 518 determines that it is not time to provide phase synchronization to the target device 504, then the method 900 continues in block 910. Otherwise, if it is time to provide phase synchronization information to the target device 504, then the method 900 continues in block 906.

In block 906, the reference device 502 (e.g., the control unit 518) updates the latest time of phase synchronization tₚ to enable determination of a next time for phase synchronization.

In block 908, the reference device 502 (e.g., the control unit 518) generates a phase synchronization command and transmits the phase synchronization command to the target device 504. Generation of the phase synchronization command can include the control unit 518 retrieving a reference clock phase count from the phase counter 514, and providing the reference clock phase count to the communication unit 516, which can then insert the reference phase count into the phase synchronization command and transmit the phase synchronization command. The method 900 continues in block 904.

In block 910, the reference device 502 (e.g., the control unit 518) determines whether it is currently time to provide frequency synchronization to the target device 504. The determination is based on whether a frequency synchronization time interval t_{freq} has elapsed from the last frequency synchronization time t_{f}. If the difference between current time (t) and the last frequency synchronization t_{f} is less than t_{freq}, the control unit 518 determines that it is not time to provide frequency synchronization to the target device 504, then the method 900 continues in block 904. Otherwise, if it is time to provide phase synchronization information to the target device 504, then the method 900 continues in block 912.

In block 912, the reference device 502 (e.g., the control unit 518) updates the latest time of frequency synchronization t_{f} to enable determination of a next time for frequency synchronization.

In block 914, the reference device 502 (e.g., the control unit 518) generates a frequency synchronization command and transmits the frequency synchronization command to the target device 504. Generation of the frequency synchronization command can include the control unit 518 causing the clock burst generator 512 to generate a reference clock burst, and providing the reference clock burst to the communication unit 516, which can then insert the reference clock burst into the frequency synchronization command and transmit the frequency synchronization command. The method 900 continues in block 904.

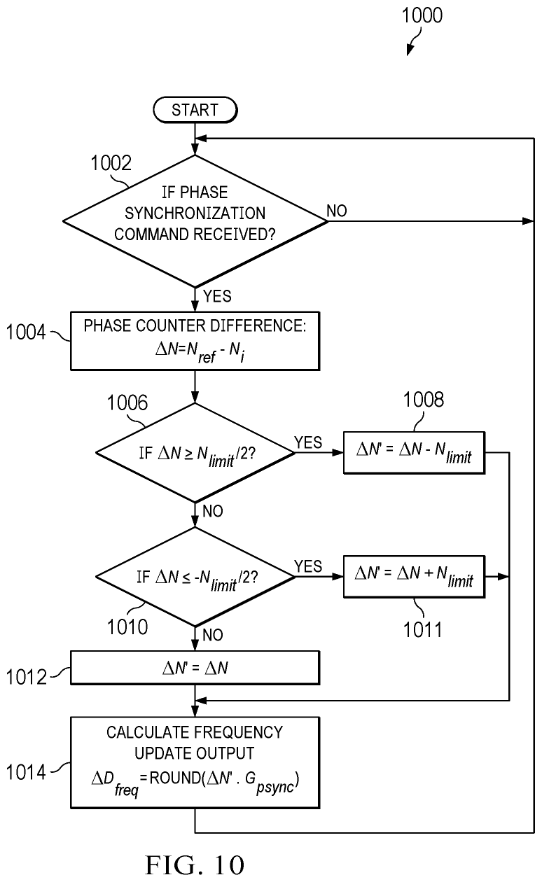

FIG. 10 is a flow diagram of an example method 1000 of phase synchronization in the target device 504. Though depicted sequentially as a matter of convenience, at least some of the actions shown can be performed in a different order and/or performed in parallel. Additionally, some implementations may perform only some of the actions shown.

In the system 500, temperature variation in between frequency synchronization command transmissions can cause higher frequency error, which results in accumulated phase error that increases quadratically over time. To reduce the effect of temperature variation, the target device 504 can carry out phase synchronization periodically in between frequency synchronization commands via the phase synchronization circuit 528. The phase synchronization circuit 528 can provide phase control signals representing periodic frequency changes ΔD_{freq} according to the phase difference between the reference clock and the target clock that decreases the phase error between the two clocks and minimizes the time error. The clock phase is captured in each device by a phase counter that resets at the beginning of the measurement and increments at each clock cycle. At the phase synchronization interval tₚₕₐₛₑ, the reference device 502 samples its phase counter N_{ref} and transmits this value in a phase synchronization command to the target device 504. When the target device 504 receives the phase synchronization command, it samples its phase counter Nᵢ and compare the values of its phase counter and the reference phase counter through a digital comparator (the phase comparator 620).

In block 1002, the target device 504 (e.g., control unit 523) determines whether a phase synchronization command has been received from the reference device 502. If a phase synchronization command has not been received, then the method 1000 continues in block 1002. If a phase synchronization command has been received, then the method 1000 continues in block 1004.

In block 1004, the target device 504 (e.g., control unit 523) extracts the reference clock phase count N_{ref} from the phase synchronization command and provides the reference clock phase count to phase synchronization circuit 528. Phase synchronization circuit 528 also retrieves a target clock phase count value Nᵢ from a target phase counter of the target device 504, and subtracts the target clock phase count from the reference clock phase count to produce a phase difference value (ΔN).

The reference and target phase counters can wrap at a value Nₗᵢₘᵢₜ. The operations of blocks 1006 through 1012 correct for such counter wrap. In block 1006, the target device 504 (e.g., the phase synchronization circuit 528) determines whether the phase difference value is greater than or equal to half of Nₗᵢₘᵢₜ. If the phase difference value is less than half of Nₗᵢₘᵢₜ then the method 1000 continues in block 1010, otherwise the method 1000 continues in block 1008.

In block 1008, the target device 504 (e.g., the phase synchronization circuit 528) subtracts Nₗᵢₘᵢₜ from the phase difference value to produce an adjusted phase difference value (ΔN′).

In block 1010, the target device 504 (e.g., the phase synchronization circuit 528) determines whether the phase difference value is less than or equal to half of −Nₗᵢₘᵢₜ. If the phase difference value is greater than half of −Nₗᵢₘᵢₜ then the method 1000 continues in block 1012, otherwise the method 1000 continues in block 1011.

In block 1011, the target device 504 (e.g., the phase synchronization circuit 528) adds Nₗᵢₘᵢₜ to the phase difference value to produce an adjusted phase difference value (ΔN′).

In block 1012, the target device 504 (e.g., the phase synchronization circuit 528) sets the adjusted phase difference value (ΔN′) to be equal to the phase difference value (ΔN).

In block 1014, the target device 504 (e.g., the phase synchronization circuit 528) provides the phase control signal including a frequency update value as:

$$Δ {D}_{freq} = round ( Δ {N}^{′} . {G}_{psync} ) \qquad ( 2 )$$

where G_{psync} is a gain value to control the steps in the frequency update based on the update rate, frequency resolution of the oscillator and phase counter resolution.

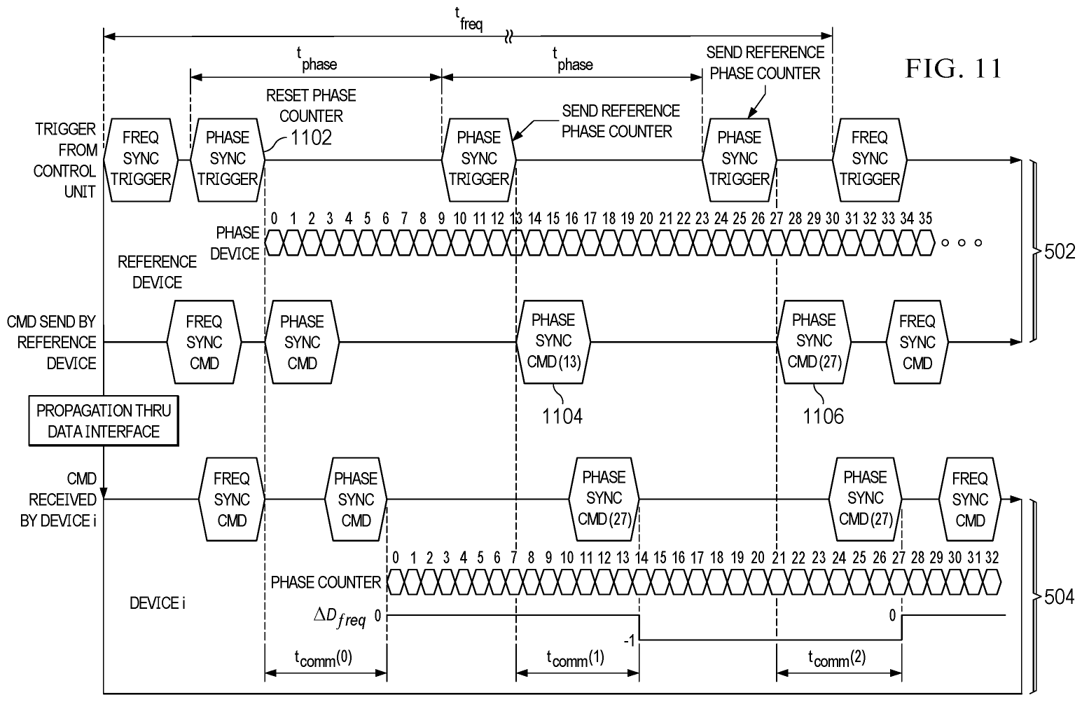

FIG. 11 is a timing diagram showing frequency and phase synchronization communication between the reference device 502 and the target device 504. FIG. 11 shows, in the reference device 502, triggering of frequency synchronization commands at interval t_{freq}, triggering of phase synchronization commands at interval tₚₕₐₛₑ, transmission of frequency and phase synchronization commands, and reference phase counter state. In the target device 504, FIG. 11 shows reception of frequency and phase synchronization commands, target phase counter state, and ΔD_{freq} based on comparison of reference and target phase counts.

In FIG. 11, the clock synchronization sequence can start by the control unit 518 in the reference device 502 triggering the frequency synchronization at a t_{freq} interval. Next, the control unit 518 triggers the phase synchronization at a tₚₕₐₛₑ interval. The reference device 502 responds to the frequency synchronization triggers from the control unit 518 by generating and sending frequency synchronization commands that include a number of reference clock cycles (a reference clock burst). The first phase synchronization trigger 1102 leads to a counter reset command (a reset count command—to reset the phase counters) followed by generation and transmission of phase synchronization commands that include the reference clock phase count. In the example shown in FIG. 11, the phase synchronization commands 1104 and 1106 include phase counts of 13 and 27, respectively. The target device 504 receives the phase synchronization command after the data interface delay of t_{comm}, which is the delay between clocks after synchronization. This data interface delay is a deterministic delay that can be determined and compensated for in data post-processing. The corresponding target device phase counts after receiving the phase synchronization commands are 14 and 27, respectively. This phase counter difference after the phase synchronization command 1104 is 1, which indicates a phase and time error between the reference and device clock. Therefore, a change in the target device frequency ΔD_{freq} is required to reduce the phase and time error. Once the phase counter values match, no further change in the target device oscillator frequency is required. This condition means that the phase and time error is minimum between the reference and target device clocks and clock synchronization has been achieved between them.

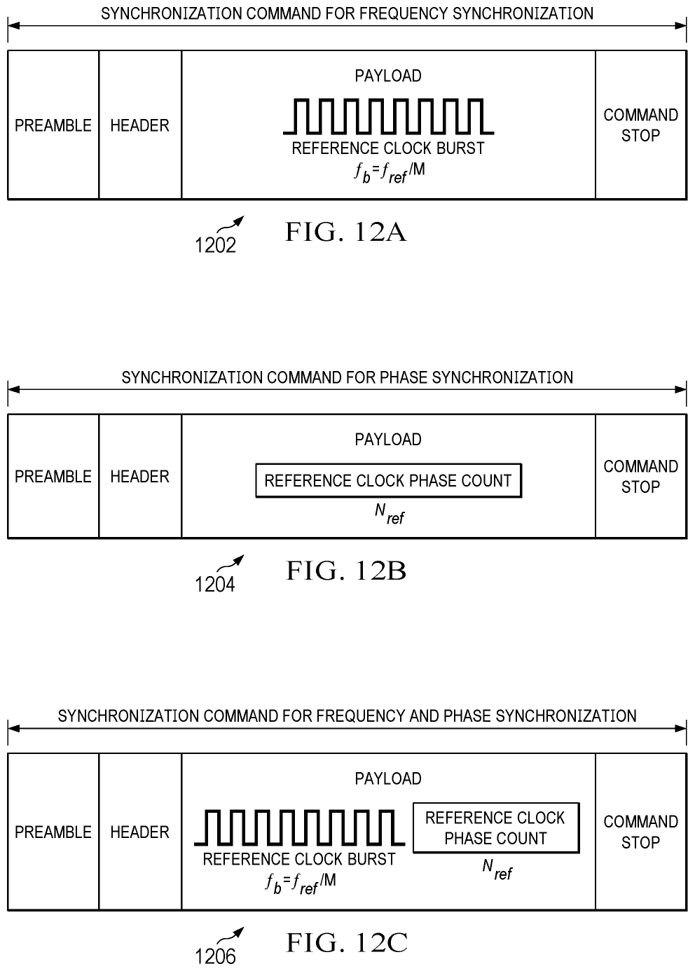

FIGS. 12A, 12B, and 12C are diagrams of example frequency and phase synchronization commands sent by the reference device 502 to the target device 504. The command 1202 of FIG. 12A is an example frequency synchronization command. The command 1204 of FIG. 12B is an example phase synchronization command. The command 1206 of FIG. 12C is an example frequency/phase synchronization command. Each of the commands starts with a preamble for synchronization between transmitting and receiving communication units in the reference and target devices, respectively. The next portion of the command is the header which can include an identifier for the command type, followed by the payload that includes the required information to be transmitted. The payload contents depend on the type of synchronization command. In the command 1202, the payload includes the reference clock burst for the frequency synchronization command. In the command 1204, the payload includes the reference phase count for the phase synchronization command. In the command 1206, the payload includes the reference clock burst followed by the reference phase count for frequency and phase synchronization in a single synchronization command. Finally, the commands end with a command stop field that identifies the end of the synchronization command.

In each of commands 1202 and 1206, the reference clock burst can be represented by a predetermined set of bits that toggle between a logical one and a logical zero, with the bit width (in time) indicating the frequency of the reference clock burst. Also, in each of commands 1204 and 1206, the reference phase clock count can be represented by a binary number having a predetermined set of bits. A command parser (e.g., part of communication unit 524/communication interface 702) can parse the command based on the command type indicated in the header to extract a set of bits representing the reference clock burst and/or a set of bits representing the reference phase count.

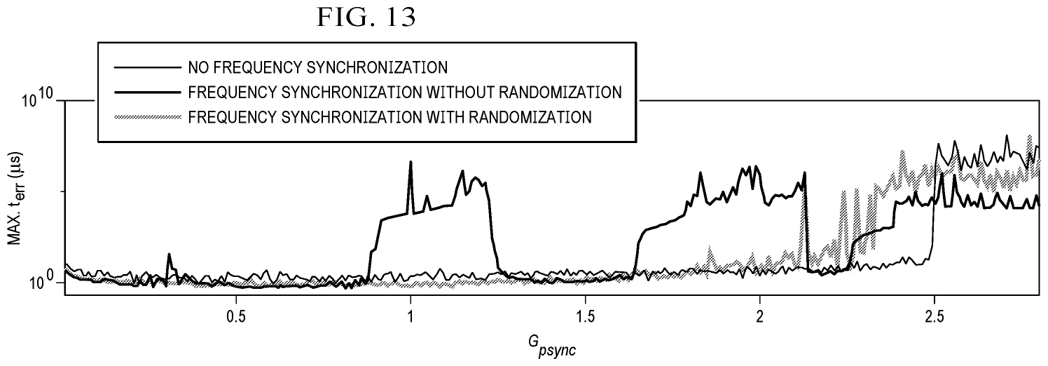

FIG. 13 is a graph of example variation of synchronization timing error with and without randomization of frequency synchronization commands. Frequency synchronization using transmission and reception of the frequency synchronization command as described herein, can reduce the frequency difference between the target clock and the reference clock at certain update intervals which reduces the synchronization time error. However, using fixed time intervals between frequency synchronization commands may cause instability in the phase synchronization at specific gain values of G_{psync}. The periodic repetition of frequency synchronization commands may lead to the accumulation of phase error that results in a continuous increase of synchronization time error over time.

In some examples of the system 500, the reference device 502 can randomize the frequency synchronization update interval through, for example, randomizing the time offset of the update interval (the time between transmission of frequency synchronization commands) by up to 10% of the update period. Example variation of synchronization time error tₑᵣᵣ versus the gain G_{psync} is shown in FIG. 13. The absence of frequency synchronization shows stable performance for a wide range of gain up to 2.5. Large values of gain above 2.5 cause large changes in the oscillator frequency that cause unstable performance. However, the absence of frequency synchronization leads to high tₑᵣᵣ because of the large frequency difference between the reference and target devices. On the other hand, using frequency synchronization without randomization may cause unstable performance for most gain values. Frequency synchronization based on randomized update interval can lead to more stable performance for most gain values while providing lower tₑᵣᵣ compared to the baseline case without frequency synchronization.

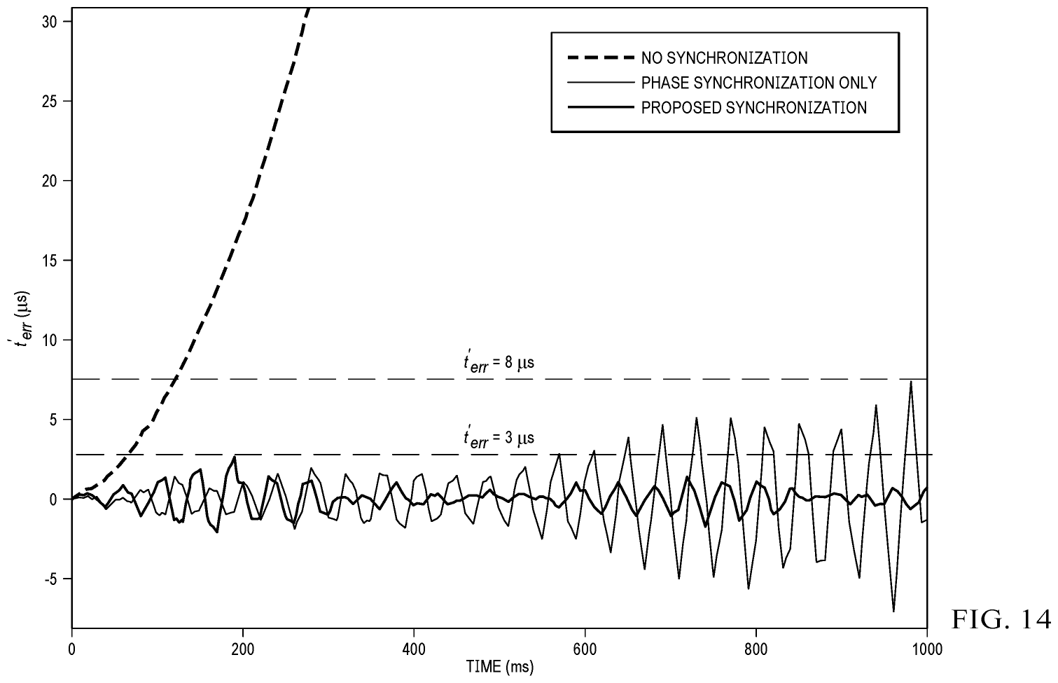

FIG. 14 is a graph of example synchronization timing error with and without phase synchronization commands. FIG. 14 shows a comparison of clock time error \acute{t}ₑᵣᵣ between the proposed clock synchronization method of the system 500 (frequency and phase synchronization), phase synchronization only, and with no synchronization. The graph shows that \acute{t}ₑᵣᵣ is very large and increases quadratically without any synchronization. Phase synchronization reduces the \acute{t}ₑᵣᵣ to less than 8 μs, but the error increases over time because of frequency drift, which cannot be compensated for with phase synchronization alone. Finally, the best result is achieved by using frequency synchronization in addition to phase synchronization as implemented in the system 500. This approach can limit the frequency drift and can keep the \acute{t}ₑᵣᵣ value less than 3 μs and prevents it from increasing over time.

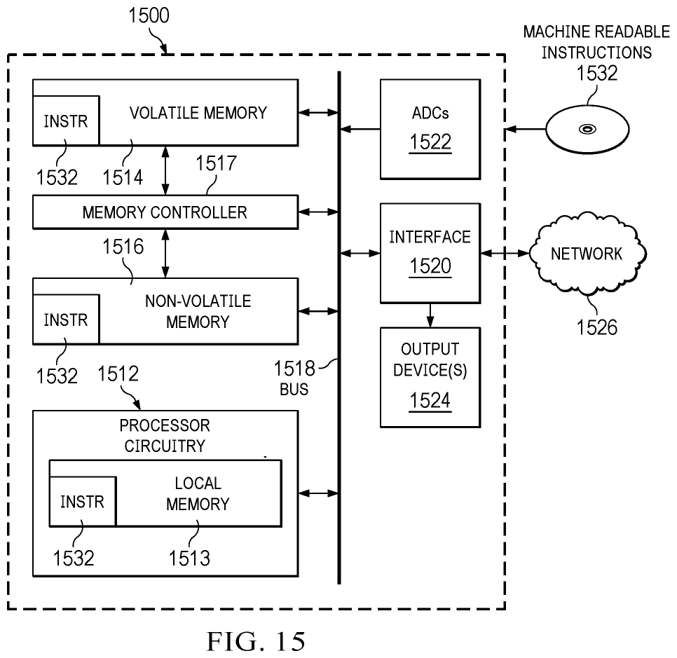

FIG. 15 is a block diagram of an example processor platform 1500 including processor circuitry structured to execute machine-readable instructions to implement the logic/functions depicted in the examples of FIGS. 5-10. For example, processor platform 1500 can be part of or include reference device 502 and target devices 504, 506, and 508 of FIG. 5, and integrated circuit 700 of FIG. 7.

Processor platform 1500 of the illustrated example can include processor circuitry 1512. The processor circuitry 1512 of the illustrated example includes hardware. For example, processor circuitry 1512 can be implemented by one or more integrated circuits, logic circuits, FPGAs, microprocessors, Central Processing Units (CPUs), Graphical Processing Units (GPUs), Digital Signal Processors (DSPs), and/or microcontrollers from any desired family or manufacturer. Processor circuitry 1512 can be implemented by one or more semiconductor-based (e.g., silicon-based) devices. In some examples, processor circuitry 1512 can implement the control units 518, 523, phase synchronization circuit 528, mode control circuit 706, DFT circuit 708, etc.

Processor circuitry 1512 of the illustrated example can include a local memory 1513 (e.g., a cache, registers, etc.). Processor circuitry 1512 of the illustrated example is in communication with a computer-readable storage device such as a main memory including a volatile memory 1514 and a non-volatile memory 1516 by a bus 1518. The volatile memory 1514 can be implemented by, for example, Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1516 may be implemented by programmable read-only memory, flash memory and/or any other desired type of non-volatile memory device. Access to the main memory 1514, 1516 of the illustrated example can be controlled by a memory controller 1517.

The processor platform 1500 of the illustrated example also includes interface circuitry 1520. The interface circuitry 1520 may be implemented by hardware in accordance with any type of interface standard, such as an Inter-Integrated Circuit (I2C) interface, a Serial Peripheral Interface (SPI), an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface. The interface circuitry 1520 may include or may be part of communication units 516 and 524.

In the illustrated example, one or more input ADCs 1522 are connected to bus 1518. The ADCs 1522 can convert analog signals to digital signals for processing by the processor circuitry 1512. ADCs 1522 can represent sampling circuit 710.

One or more output devices 1524 can be connected to the interface circuitry 1020 of the illustrated example. The output device(s) 1524 can include circuits such as driver circuits.

Machine-readable instructions 1532 can be stored in volatile memory 1514 and/or non-volatile memory 1516. Upon execution by the processor circuitry 1512, the machine-readable instructions 1532 cause the processor platform 1500 to perform any or all of the functionality described herein attributed to the reference device 502, target devices 504, 506, and 508, integrated circuit 700, and methods 800, 900, and 1000.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Modifications are possible in the described embodiments, and other embodiments are possible, within the scope of the claims.

What is claimed is:

1. A device comprising:
a clock source having a clock output;
a counter having a counter clock input and a count output, the clock output coupled to the counter clock input;
a command generation circuit having a frequency input, a phase input, and a command output, the frequency input coupled to the clock output, and the phase input coupled to the count output; and
a communication interface coupled to the command output.

2. The device of claim 1, further comprising a frequency divider coupled between the clock source and the frequency input.

3. The device of claim 1, wherein the command generation circuit is configured to:
receive a clock signal at the frequency input;
receive a count value at the phase input;
transmit a first command including the clock signal at the command output via the communication interface; and
after transmitting the first command, transmit a second command including the count value at the command output via the communication interface.

4. The device of claim 3, wherein the command generation circuit is configured to transmit multiple second commands between consecutive first commands.

5. The device of claim 3, wherein the second command includes a reset count command.

6. The device of claim 3, wherein the second command includes the clock signal, or the first command includes the count value.

7. The device of claim 3, wherein the command generation circuit is configured to transmit the first and second commands at random intervals.

8. The device of claim 1, wherein the communication interface, the clock source, the counter, and the command generation circuit are part of an integrated circuit, and the integrated circuit further comprising:
a sampling circuit having a sense input, a sample output, and a sampling clock input, the sampling clock input coupled to the clock output, the sampling circuit configured to receive a measurement signal at the sense input and provide samples of the measurement signal at the sample output; and
a signal processing circuit having a processing input and a processing output, the processing input coupled to the sample output, the signal processing circuit configured to provide signals representing spectral components of the measurement signal at the processing output.

9. The device of claim 8, wherein the measurement signal includes at least one of: a current signal through a device under test (DUT), or a voltage signal across the DUT.

10. The device of claim 9, wherein the DUT is a battery.

11. A device comprising:
a communication interface;
a command processing circuit having a command input, a reference frequency output and a reference phase output, the command input coupled to the communication interface;
a clock synchronization circuit having a reference frequency input, a reference phase input, and a frequency control output, the reference frequency output coupled to the reference frequency input, and the reference phase input coupled to the reference phase output, the clock synchronization circuit including a frequency synchronization circuit and a phase synchronization circuit; and
a controllable clock source having a frequency control input and a clock output, the frequency control input coupled to the frequency control output.

12. The device of claim 11, wherein the command processing circuit is configured to:
receive a first command including a reference clock signal;
receive a second command including a reference count value;
provide the reference clock signal at the reference frequency output; and
provide the reference count value at the reference phase output; and
wherein the phase synchronization circuit includes:
a counter having a counter clock input and a count output, the counter clock input coupled to the clock output; and
a phase comparator having first and second inputs and a comparator output, the first input coupled to the count output, the second input coupled to the reference phase input, and the comparator output coupled to the frequency control output, the phase comparator is configured to generate a first frequency control signal based on a comparison between the reference count value and a target count value; and
wherein the frequency synchronization circuit includes:
a phase detector having first and second detector inputs and a detector output, the first detector input coupled to the reference frequency input, and the second detector input coupled to the clock output; and
a charge pump and a loop filter coupled between the detector output and the frequency control output; and
wherein the frequency synchronization circuit is configured to provide a second frequency control signal based on a phase difference between the reference clock signal and a target clock signal at the clock output.

13. The device of claim 12, further comprising a frequency divider coupled between the clock output and the second detector input.

14. The device of claim 12, further comprising a processing circuit coupled between the comparator output, the detector output, and the frequency control output, the processing circuit configured to provide a third frequency control signal based on the first and second frequency control signals.

15. The device of claim 11, wherein the communication interface, the command processing circuit, and the clock synchronization circuit are part of an integrated circuit, and the integrated circuit further comprising:
a sampling circuit having a sense input, a sample output, and a sampling clock input, the sampling clock input coupled to the clock output, the sampling circuit configured to receive a measurement signal at the sense input and provide samples of the measurement signal at the sample output; and
a processing circuit having a processing input and a processing output, the processing input coupled to the sample output, the processing circuit configured to provide signals representing spectral components of the measurement signal at the processing output.

16. The device of claim 15, wherein the measurement signal includes at least one of: a current signal through a device under test (DUT), or a voltage signal across the DUT.

17. The device of claim 16, wherein the DUT is a battery.

18. An integrated circuit comprising:
a communication interface;
a controllable clock source having a frequency control input and a clock output;
a counter having a clock input and a count output, the clock input coupled to the clock output;
a command generation circuit having a frequency input, a phase input, and a command output, the frequency input coupled to the clock output, the phase input coupled to the count output, and the command output coupled to the communication interface;
a command processing circuit having a command input, a reference phase output, and a reference frequency output, the command input coupled to the communication interface; and
a clock synchronization circuit having a reference phase input, a reference frequency input, and a frequency control output, the reference phase input coupled to the reference phase output, the reference frequency output coupled to the reference frequency input, and the frequency control output coupled to the frequency control input, the clock synchronization circuit including a frequency synchronization circuit and a phase synchronization circuit.

19. The integrated circuit of claim 18, further comprising a mode control circuit having a mode control input, the mode control circuit configured to:
responsive to the mode control input having a first state, cause the command generation circuit to:
receive a clock signal at the frequency input;
receive a count value at the phase input;
transmit a first command including the clock signal at the command output via the communication interface; and
transmit a second command including the count value at the command output via the communication interface; and
responsive to the mode control input having a second state:
cause the command processing circuit to receive a first command including a reference clock signal and provide the reference clock signal at the reference frequency output;
cause the command processing circuit to receive a second command including a reference count value and provide the reference count value at the reference phase output;
cause the clock synchronization circuit to provide a frequency control signal at the frequency control output based on the reference count value and the reference clock signal; and
cause the controllable clock source to provide a clock signal at a second clock output based on the frequency control signal.

20. The integrated circuit of claim 19, further comprising
a sampling circuit having a sense input, a sample output, and a sampling clock input, the sampling clock input coupled to the clock output, the sampling circuit configured to receive a measurement signal at sense input and provide samples of the measurement signal at the sample output; and
a signal processing circuit having a processing input and a processing output, the processing input coupled to the sample output, the signal processing circuit configured to provide signals representing spectral components of the measurement signal at the processing output.

21. The integrated circuit of claim 20, wherein the measurement signal includes at least one of: a current signal through a device under test (DUT), or a voltage signal across the DUT.

22. The integrated circuit of claim 21, wherein the DUT is a battery.

23. A system comprising:
a Device Under Test (DUT) monitoring device including:
a stimulus generation circuit having a stimulus output;
an impedance spectroscopy circuit having a first spectroscopy input, a second spectroscopy input, and an impedance spectroscopy input;
a current sense circuit having a current sense output;
a first measurement device including:
a synchronization command processing circuit having a command input;
a clock synchronization circuit coupled to the synchronization command processing circuit, the clock synchronization circuit having a frequency control output;
a controllable clock source having a frequency control input and a first clock output, the frequency control input coupled to the frequency control output;
a first sampling circuit having a DUT input, a first sample output, and a first clock input, the first clock input coupled to the first clock output, and the first sampling circuit configured to receive a voltage measurement signal at the DUT input and provide samples of the voltage measurement signal at the first sample output; and
a first processing circuit having a first processing input and a first processing output, the first processing input coupled to the first sample output, the first processing output coupled to the first spectroscopy input, and the first processing circuit configured to provide first signals representing spectral components of the voltage measurement signal at the first processing output; and
a second measurement device including:
a reference clock source having a reference clock output;
a counter having a second clock input and a count output, the second clock input coupled to the reference clock output;
a synchronization command generation circuit having a frequency input, a phase input, and a command output, the frequency input coupled to the reference clock output, the phase input coupled to the count output, and the command output coupled to the command input;
a second sampling circuit having a current sense input, a second sample output, and a third clock input, the third clock input coupled to the reference clock output, the current sense input coupled to the current sense output, and the second sampling circuit configured to receive a current measurement signal at the current sense input and provide samples of the current measurement signal at the second sample output; and
a second processing circuit having a second processing input and a second processing output, the second processing input coupled to the second sample output, the second processing output coupled to the second spectroscopy input, and the second processing circuit configured to provide second signals representing spectral components of the current measurement signal at the second processing output.

24. The system of claim 23, wherein the DUT is a battery.

25. A method comprising:
generating, by a first device, a reference clock signal;
providing, by the first device, a reference count value based on counting cycles of the reference clock signal;
providing, by the first device, a divided clock signal based on dividing the reference clock signal,
providing, by the first device, a first command including the divided clock signal;
providing, by the first device, a second command including the reference count value;
receiving, by a second device, the first command;
receiving, by the second device, the second command;
generating, by the second device, a target clock signal;
determining, by the second device, a target count value based on the target clock signal; and
adjusting, by the second device, a frequency and a phase of the target clock signal based on the divided clock signal and a difference between the reference count value and the target count value.
